(19) United States
(12) Patent Application Publication
(10) Pub. No.: US 2005/0109616 A1
(43) Pub. Date: May 26, 2005

(54) Sputtering apparatus

(75) Inventors: Tatsuo Ohta, Otsuki-shi (JP); Satoshi Nakano, Tokyo (JP); Setsuo Tokuhiro, Tokorozawa-shi (JP)

Correspondence Address: Finnegan, Henderson, Farabow,;Garrett & Dunner, L.L.P., 1300 I Street, N.W., Washington, DC, 20005-3315, US

(73) Assignee: KONICA MINOLTA OPTO, INC.

(21) Appl. No.: 10/971,112

(22) Filed: Oct. 25, 2004

(30) Foreign Application Priority Data
Oct. 28, 2003 (JP) JP2003-367345

(51) Int. Cl. C23C 14/00

(52) U.S. Cl. 204/298.18; 204/298.16; 204/298.17; 204/298.21

(57) ABSTRACT

A sputtering apparatus for applying a thin film coating to a substrate containing, in a vacuum chamber, at least two cylindrical targets and at least two magnets each juxtaposed to one of the targets so as to generate a magnetic field in a vicinity of an outer surface of the target, wherein, the following relationship is satisfied d1≦3d2, provided that d1 is a distance between the outer surfaces of the two targets and d2 is any one of distances between the outer surfaces of the targets and the substrate.

### TECHNICAL FIELD

The present invention relates to a sputtering apparatus.

### BACKGROUND

Vacuum evaporation methods using, for example, a resistance heating system and an electron beam heating system, have been utilized to form various thin films, for example, optical thin films and conductive thin films. However, films formed by a vacuum evaporation method have not been fully dense enough and the refractive index of optical films formed by an evaporation method has been relatively easily affected by temperature or moisture, which tend to cause changes in the spectroscopic reflection properties. In order to increase the density of films formed by an evaporation method, an ion assisted evaporation method has been proposed, in which a film is formed while ions of oxygen or argon are irradiated over the substrate surface. However, this method tends to exhibit problems in that (i) uniform irradiation of ions over a wide area of a substrate is rather difficult; and (ii) productivity of such films is not fully satisfactory since it is rather difficult to increase the evaporating rate.

Recently, a magnetron sputtering method has become into wide use. In this method, a film is formed by depositing atoms on a substrate, the atoms being forced out of a target by bombarding cations generated through a glow discharge and further accelerated by an electrical field. In a sputtering method, an inert gas, for example, argon, is introduced into a vacuum chamber to generate a glow discharge. In order to carry out reactive sputtering, a reactive gas, for example, oxygen or nitrogen, is further introduced into the vacuum chamber. Although, this method may consume more time to form a thin film compared to an evaporation method, a film formed by this method has greater density, better physical or chemical stability, and a stronger adhesive force onto the substrate.

The following two methods have also been known: (i) a magnetron sputtering method, in which sputtering rate is enhanced by forming a magnetic field near the surface of the target to hold high density of cations generated by glow discharge; and (ii) a dual magnetron sputtering method, in which alternate voltages are alternately applied to a pair of targets (for example, refer to Patent Documents 1 and 2).

(Patent Document 1)
Japanese Patent Publication Open to Public Inspection (hereafter referred to as JP-A) No. 10-158830

(Patent Document 2)
JP-A No. 11-71667

However, in conventional sputtering methods, for example, disclosed in Patent Documents 1 and 2 tend to exhibit the problem that, when a high rate film forming is conducted, oxidation of deposited film is not fully sufficient and the transparency of the film tends to be slightly lost. Also, when a high rate sputtering is carried out in a transient region between a metallic region and an oxide region, as shown in FIG. 8, film forming rate and transparency of the sputtered film may drastically change depending on changes in oxygen pressure or in sputtering voltage, in all the voltage region of V1 to V3.

When a pulse voltage or a dual-phase voltage is applied to a target, a considerable amount of charge transfer due to ions and electrons occurs and the amount of ions or electrons irradiated onto the substrate surface increases, resulting in occurrences of (i) a reverse sputtering by which the substrate is sputtered; (ii) an extraordinary increase in the substrate temperature; (iii) cracking, peeling or staining of the film; (iv) loss of flatness of the film; or (v) occurrence of white turbidity in the film.

When sputtering is carried out in a gas mixture of oxygen and argon, accumulation of positive charge occurs due to a formation of an oxide film on the target surface, which may cause insufficient collision of cations to the target resulting in a decrease in sputtering speed. Alternatively, when a plus voltage applied to the target is raised to remove the oxide film formed on the target, the following problems may occur: (i) reverse sputtering of the substrate; (ii) damage of the substrate due to an extraordinary discharge; and (iii) defective operation of the device.

### SUMMARY OF THE INVENTION

An object of the present invention is to provide a sputtering apparatus which enables formation of a highly functional optical film at a high rate, the sputtering apparatus being free from the problems described above.

One embodiment of the present invention is a sputtering apparatus for applying a thin film to a substrate, containing at least two cylindrical targets or two planar targets in the vacuum chamber, and at least two magnets juxtaposed to each of the targets so as to generate a magnetic field in the vicinity of an outer surface of the target, and exhibiting the following features: (i) a thin film is formed by applying a voltage to each of the target while a discharge gas and a reactive gas are introduced into the vacuum chamber; and (ii) a relationship between the distance between the outer surfaces of the two targets (d1) and the distance between each of the outer surface of the targets and the substrate (d2) satisfies a specified condition.

### BRIEF DESCRIPTION OF THE DRAWINGS

FIG. 1 is a perspective view showing the external structure of a sputtering apparatus.

FIG. 2 is a top view showing the structure in a vacuum chamber.

FIG. 3 is a top view for describing d1, d2 and angle θ.

FIGS. 4(a)-4(d) are top views describing motion of a sputtering apparatus.

FIGS. 5(a)-5(b) shows waveforms of applied voltages.

FIG. 6 is a top view showing the internal structure of a sputtering apparatus of the 2nd embodiment.

FIG. 7 is a top view showing an internal structure of a sputtering system of the 3rd embodiment.

FIG. 8 shows graphs describing areas of the metallic region, the transient region and the oxide region.

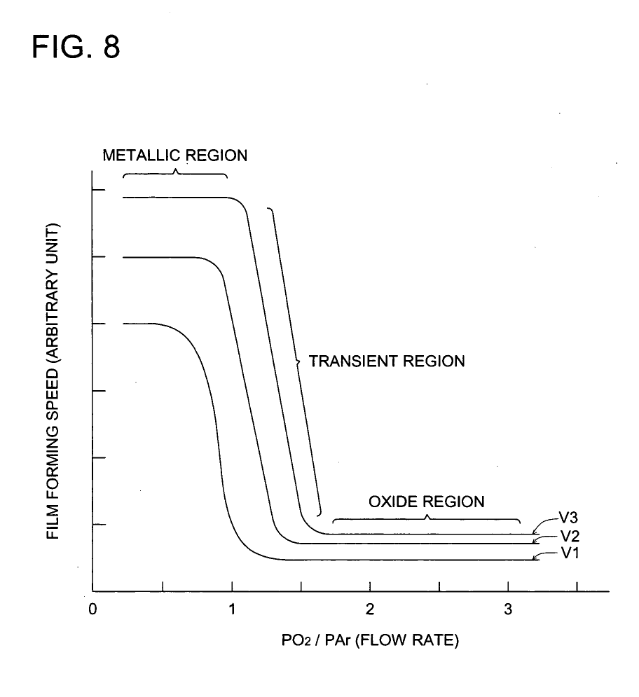

### DESCRIPTION OF THE PREFERRED EMBODIMENTS

The preferred embodiments for practice of the present invention will now be described, however, the present invention is not limited thereto.

(1) A sputtering apparatus for applying a thin film coating onto a substrate containing:
a vacuum chamber;
at least two cylindrical targets or two planar targets in the vacuum chamber; and
at least two magnets each juxtaposed to one of the targets so as to generate a magnetic field in a vicinity of an outer surface of the target,
wherein:
(i) the thin film coating is formed by applying a voltage to each of the targets while a discharge gas and a reactive gas are introduced into the vacuum chamber,
(ii) Formula (1) is satisfied in the vacuum chamber,
   d1≦3d2 Formula (1)
provided that d1 is a distance between the outer surfaces of the two targets and d2 is any one of distances between the outer surfaces of the targets and the substrate.

(2) The sputtering apparatus of Item 1, wherein, Formula (2) is satisfied in the vacuum chamber.
d1≦2d2 Formula (2)

(3) The sputtering apparatus of Item 1 or 2, wherein, Formula (3) is satisfied in the vacuum chamber.
θ≦160 Formula (3)
provided that:
   (i) when the two targets are cylindrical, θ is defined as an angle between two normal lines drawn on outer circles of the targets in a cross-section plane containing the two targets which is perpendicular to a side surface of one of the cylindrical targets, each normal line being drawn at a point where the magnetic field is strongest in the outer circle; and
   (ii) when the two targets are planar, θ is defined as an angle between two perpendicular lines of the targets in a cross-section plane containing the two targets which is perpendicular to a side line of one of the planar targets.

(4) The sputtering apparatus of aspect 3, wherein, Formula (4) is satisfied in the vacuum chamber.
45°≦θ≦100° Formula (4)

(5) The sputtering apparatus of any one of Items 1 to 4, wherein, the targets are cylindrical and rotate while sputtering.

(6) The sputtering apparatus of any one of Items 1 to 5, further containing a protection container which surrounds the targets and has an aperture open to a front,
wherein, the protection container has a discharge gas inlet on a back wall, while a reactive gas inlet is provided at a portion of the vacuum chamber between the targets and the substrate.

(7) The sputtering apparatus of any one of Items 1 to 6, wherein, polarities of electrical power supplied to the two targets are different from each other and change with time.

According to the embodiment described in Item 1, the targets are arranged to be closer to each other in accordance with the arrangement satisfying Formula (1). A closer distance between the targets causes a much larger electrical potential difference than electrical potential differences between the targets and the substrate. Due to the large electrical potential difference between the two targets, charged particles, for example, argon ions, oxygen ions and electrons existing in the discharge gas and the reactive gas migrate mainly between the two targets instead of migrating to the substrate surface. Accordingly, damage to the glass substrate is avoided even when the applied voltage is increased, resulting in a high production rate of high quality optical thin films without cracking, peeling and white turbidity.

When a sputtering apparatus is structured so as to satisfy Formula (2), according to the embodiment described in Item 2, not only for a glass substrate, but also for a plastic substrate, the same effect as described above for the invention according to Item 1 is obtainable.

According to the embodiment described in Item 3, a sputtering apparatus is constructed so as to satisfy Formula (3). Since the discharge occurs mainly between the two targets when voltages are applied to the targets, reverse sputtering of the substrate surface is reduced and high formation rate of a film is realized.

According to the embodiment described in Item 4, by structuring the sputtering apparatus so as to satisfy Formula (4), an electrical field is focused in the vicinity of the substrate, by which a high depositing rate of target materials is maintained, resulting in a high production rate of high quality optical films.

According to the embodiment described in Item 5, the targets are rotated while sputtering, which prevents local deformation of the targets while sputtering and enables effective utilization of the targets.

According to the embodiment of Item 6, a discharge gas inlet is provided on a back wall of a target protection container and a reaction gas inlet is provided in a portion between the targets and the substrate. According to this configuration, a high distribution density of a discharge gas in the vicinity of the targets and a high distribution density of a reactive gas in the vicinity of the substrate is attained, which results in the following effects: (i) while a film is being formed by sputtering, a stable glow discharge in the vicinity of the targets is obtained while formation of an oxide film on the target surface is avoided; and (ii) even if the target material is in a low oxidation state, oxidation of the target material in the vicinity of the target or on the substrate surface is promoted and a highly transparent optical film is obtained.

According to the embodiment described in Item 7, an oxide film formed on the surface of the targets is effectively removed and damage to the substrate due to the discharge is prevented.

Next, the invention will be explained in further detail.

### The 1st Embodiment of the Present Invention

The 1st embodiment of the present invention is described based on drawings.

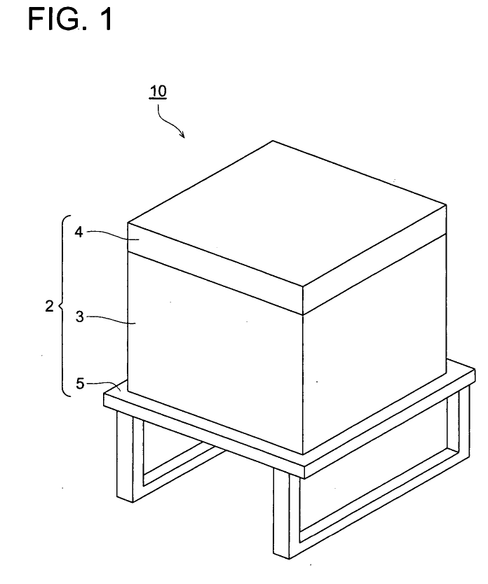

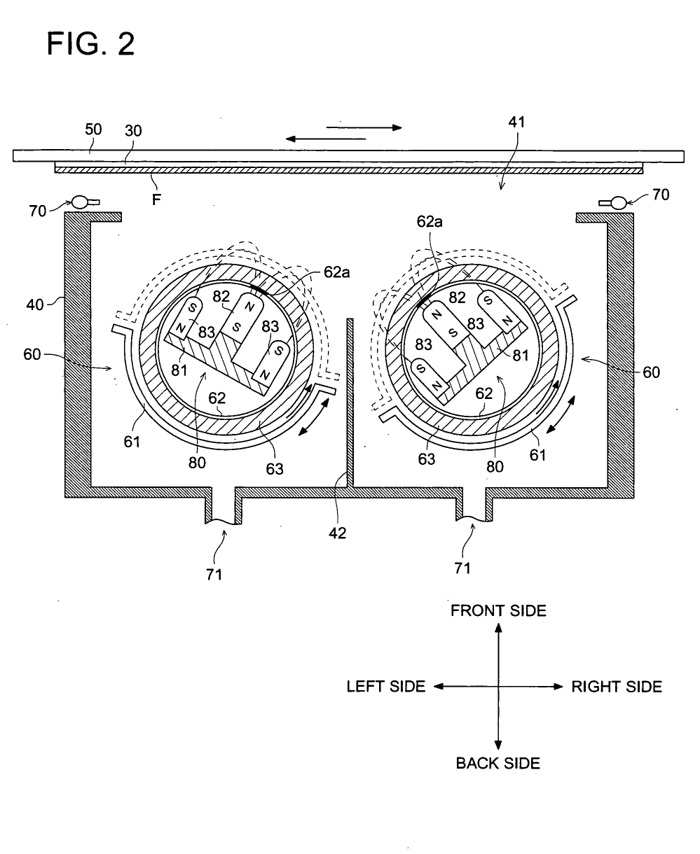

As shown in FIGS. 1 and 2, sputtering apparatus 10 contains targets 63, magnets 80 (81, 82 and 83), and substrate 30 in vacuum chamber 2 of which the housing is a rectangular box. In FIGS. 2-7, graphic illustrations of vacuum chambers 2 are omitted, and symbol F represents the thin film.

Vacuum chamber 2 includes lid 4 and base plate 5 which form airtight seals at, respectively, top and bottom faces of bell jar body 3 being square prism. Film forming is performed in the interior space of vacuum chamber 2. Bell jar body 3 and lid 4 freely moves up and down in relation to base plate 5, and lid 4 of bell jar body 3 can be easily opened and closed employing a hinge mechanism, which is not illustrated.

In vacuum chamber 2, further provided are: (i) target protection container 40 which surrounds the perimeters of targets 63; (ii) aperture 41 open to the front; and (iii) partition 42 which prevents each of the targets from being affected by scattered particles from the other target while a film is being formed by sputtering.

Substrate holder plate 50 for supporting substrate 30 is provided facing to the aperture 41 of target protection container 40.

Substrate holder 50 is supported by a wall of vacuum chamber 2 so that the substrate holder can move freely to the left or right in FIG. 2 while being sputtering. Substrate holder 50 is electrically conductive, and is electrically connected to bell jar body 3, lid 4, and to base plate 5. When sputtering is being carried out, it serves to ground the apparatus.

Substrate 30 is held by substrate holder 50. Examples of a plastic substrate include: an acryl resin, a polycarbonate resin, a Zeonex resin (a product name of Zeon Corp.), an Arton resin (a product name of JSR Corp.), and other common resin of excellent transparency. As examples of a glass substrate, any glass item used for the following purposes is acceptable, for example, a lens, a mirror, a prism, an optical waveguide, fiber optics, a protective cover for a display, and other common optical glass elements.

Two cylindrical target blocks 60 are installed in both the right and left portions in vacuum chamber 2, and two electrically conductive shutters 61 respectively surround the two cylindrical target blocks 60.

Although target block 60 serves as a negative electrode and discharge is carried out between the substrate holder 50, film forming is not performed while a shutter 61 is existing between target block 60 and substrate holder 50, as shown by a dotted line shows in FIG. 2.

Reactive gas inlet 70 for introducing reactive gas into vacuum chamber 2 is provided near the front-end of target protection container 40, while discharge gas inlet 71 for introducing discharge gas into vacuum chamber 2 is provided on the back wall of target protection container 40.

As a discharge gas, argon gas, helium gas, and mixed gases containing argon as a main component (for example, argon gas containing 10% by weight oxygen) are usable. As a reactive gas, oxygen gas, nitrogen gas, and mixed gases containing oxygen as a main component (for example, oxygen which contains 30% by weight argon) are usable.

Target block 60 contains: (i) cylindrical and electrically conductive stainless steel or copper target holder 62; and (ii) cylindrical target 63 which is fitted to target holder 62, and the inner surface of target 63 closely contacts the peripheral surface of target holder 62.

Examples of target materials include: (i) for low refractive-index materials, magnesium fluoride and silicon; (ii) for medium refractive-index materials, aluminum and yttrium; and (iii) for high refractive-index materials titanium, tantalum, niobium, hafnium, tungsten, chromium, cerium, zirconium and lower oxidation state oxides of these materials.

In the center of target holder 62, magnet 80 which is fixed to base plate 5 is assembled.

Magnet 80 contains (i) iron core 81 which is supported with a rod (not shown) vertically fixed to the base plate 5; (ii) 1st magnet array 82 fixed to the core 81; and (iii) 2nd magnet arrays 83 fixed to the core 81, which surround the 1st magnet array. First and 2nd magnet arrays 82 and 83 extend along the longitudinal direction (being the vertical direction) of target holder 62. First magnet array 82 serves as a “N” pole, and the 2nd magnet arrays 83 serves as “S” poles, each polarity being the polarity of each end of the magnet close to the inner surface of target holder 62. The distances between the ends of the magnet arrays and target holder 62 are arranged to be almost the same. Therefore, in an arbitrary cross section of a target, many magnetic field lines can be drawn, as shown in FIG. 2 with broken lines. Since the same magnetic field lines can be drawn anywhere in the longitudinal direction of the target 63, a magnetic field exists over almost half of the surface of the cylindrical target close to substrate 30.

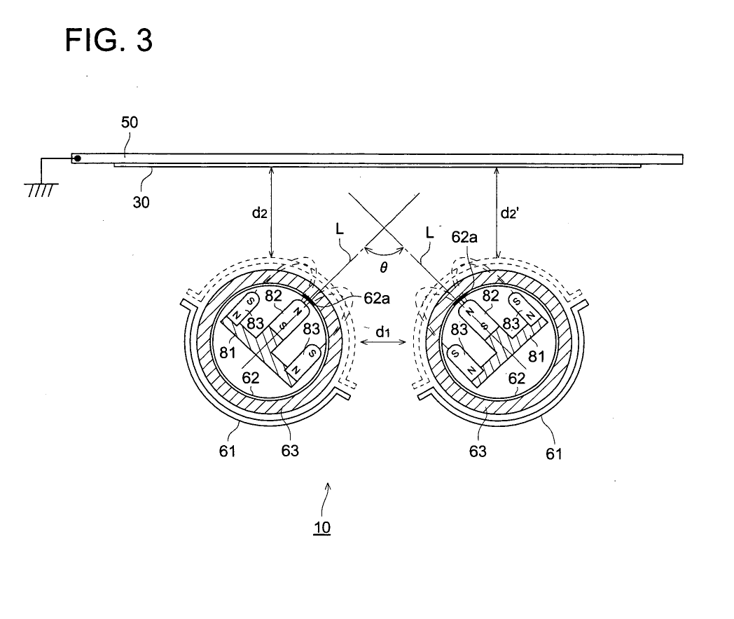

Magnetic field lines originating from the “N” pole of 1st magnet array 82 pass from inside to outside through target holder surface 62a nearest to the pole of 1st magnet array 82 and reach the “S” poles of 2nd magnet arrays 83, again passing through the target holder surface 62 from outside to inside. In the present invention, the sputtering apparatus is arranged so as to satisfy Formula (3), namely, θ≦160° (refer to FIG. 3), wherein, θ is defined as an angle between two normal lines L (in FIG. 3) drawn on outer circles of the targets in a cross-section plane containing the two targets, which is perpendicular to a side surface of one of the cylindrical targets, each normal line being drawn at a point where the magnetic field is strongest in the outer circle. The point where the magnetic field is strongest in the outer circle may correspond to the point in the outer circle which is nearest to the n pole of the 1st magnet array. Angle θ is defined in a range of 0<θ<360°.

Also, the sputtering apparatus of the present invention is structured so as to satisfy Formula (1), namely, d1≦3d2, provided that d1 is the distance between the outer surfaces of the two targets 63 and d2 is any one of distances between the outer surfaces of the targets and substrate 30. Further, the sputtering apparatus of the present invention is arranged so that the distances of the two targets 63 and substrate 30 become equal. However, when the above distances are different, by representing one distance as d2 and the other as d2′, the sputtering apparatus is arranged so as to satisfy both d1≦3d2 and d1≦3d2′.

The center space of target holder 62 which is used to install the above described magnet 80 is also used to pass cooling water to prevent overheating of target holder 62 and target 63.

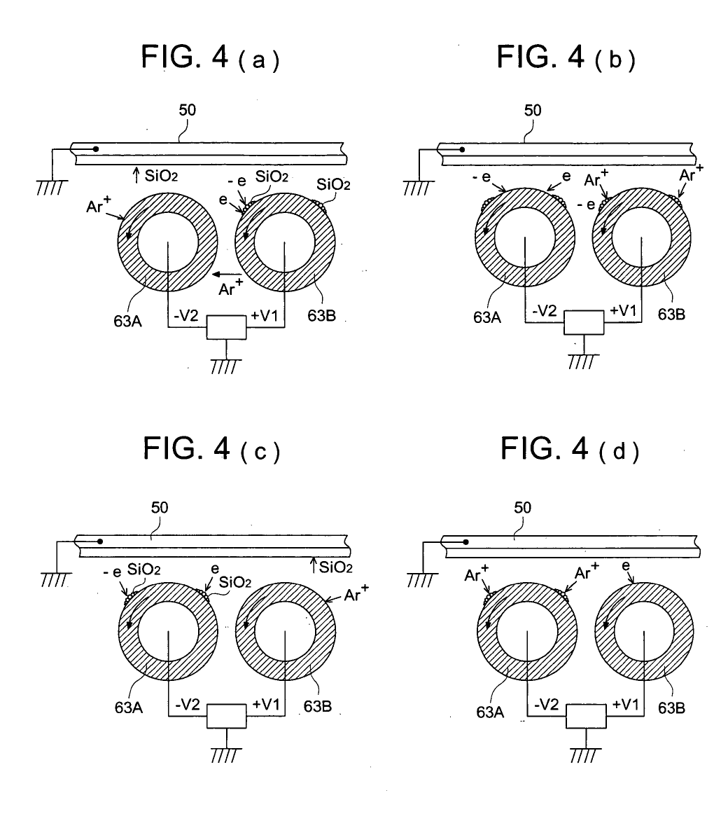

Next, performance of sputtering apparatus 10 is described using FIG. 4 in a case, for example, when silicon is used as a target material to form thin film F of silicon oxide on the surface of substrate 30.

First, bell jar body 3 and lid 4 are opened, and each target holder 62 is equipped with target 63. Substrate 30 is held by substrate holder 50 with one surface of the substrate facing target block 60. After closing bell jar body 3 and lid 4, a vacuum evacuating system (not illustrated) is operated to evacuate the inside of bell jar 2 to a prescribed vacuum level followed by introducing discharge gas and reactive gas of a prescribed mixing ratio through gas inlets 70 and 71 to maintain a prescribed inside pressure within bell jar 2.

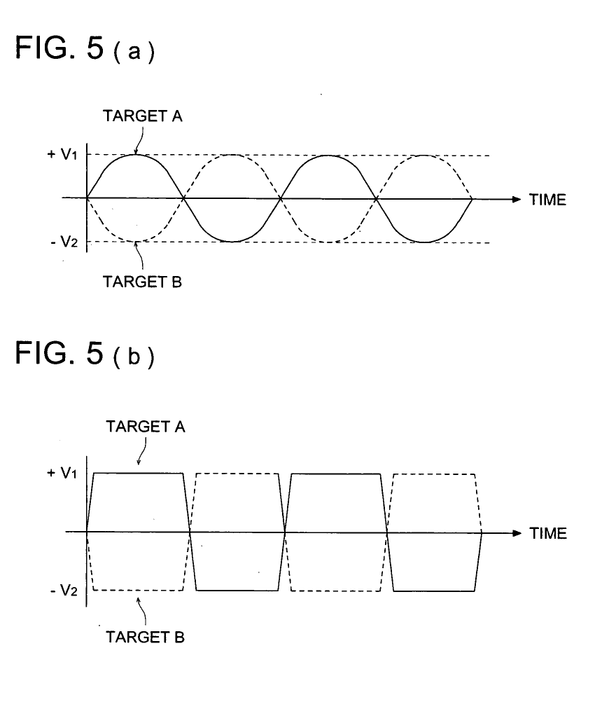

Cooling water is passed through target holders 62 and all of shutters 61 are confirmed to be closed. While keeping the substrate holder at a ground potential, two sinusoidal wave voltages, each of which changes in a range of +V₁ to −V₂ as shown in FIG. 5(a), are applied to target holders 62 so that the polarities of the two targets are always opposed, namely, when one target is working as a cathode, the other target is working as an anode and vice versa, while the polarities change with time. A square wave voltage as shown in FIG. 5(b) may be also applied instead of a sinusoidal wave. In FIGS. 5(a) and 5(b), the solid line and the dotted line represent voltage changes of, respectively, target A and Target B. +V₁ means the peak value of positive voltage which is in the range of 0 to 2000 volts, and −V₂ means the peak value of negative voltage which is in the range of −2000 to 0 volt, while the frequency is usually in the range of 20 to 100 kHz.

Plasma of a discharge gas is generated between substrate holder 50 and target block 60 after starting rotation of target holder 62, while conductive shutter 61 is opened. Substrate holder 50 is moved left or right at a predetermined speed.

When a negative voltage (−V₂) is applied to target 63A, as shown in FIG. 4(a), the surface of target 63A is sputtered by positively charged argon ions (Ar+) which are formed by the discharge. The scattered target material in the vacuum is oxidized by oxygen contained in the gas mixture and is deposited on the surface of substrate 30 as silicon oxide (SiO₂).

On the other hand, on the surface of target 63B to which a positive voltage (+V₁) is applied, a silicon oxide film is formed and electrons and negative charges attracted to the positive target are deposited on it.

Since the distance between the outer surfaces of targets 63A and 63B, represented by d1, and any one of distances between the outer surfaces of the targets and the substrate represented by d2 satisfy Formula (1), argon ions existing in the vicinity of target 63B applied with a positive voltage, are more likely to migrate to target 63A applied with a negative voltage than to migrate to substrate 30, resulting in reducing reverse sputtering of the substrate surface by argon ions. Thus, formation of a high quality film becomes possible.

Subsequently, when a negative voltage (−V₂) is applied to target 63B having a silicon oxide film deposited on the surface, as shown in FIG. 4(b), positively charged argon ions are strongly attracted to and collide with negative target 63B, by which the silicon oxide film formed on the surface is removed.

Moreover, as shown in FIG. 3, the sputtering apparatus of the present invention is structured so as to satisfy Formula (3) where θ represents an angle between two normal lines L drawn on outer circles of the targets in a cross-section plane containing the two targets, which is perpendicular to a side surface of one of the cylindrical targets, each normal line being drawn at a point 62a closest to the “N” pole of magnet array 82 which is also the point where the magnetic field is strongest in the outer circle. This causes migration of a major part of electrons and negatively charged particles existing near target 63B (applied with a negative voltage (−V₂)) to the surface of target 63A (applied with a positive voltage (+V₁)), and migration of these particles to substrate 30 is reduced. Thus, an extraordinary increase in temperature of substrate 30 is avoided and formation of a high quality film becomes possible.

After the silicon oxide film deposited of the surface of negatively charged target 63B is removed, the surface of target 63B is sputtered by positively charged argon, as shown in FIG. 4(c), and scattered target material in the vacuum is oxidized by the oxygen contained in the gas mixture and is deposited on the surface of substrate 30 as silicon oxide (SiO₂).

On the other hand, on the surface of target 63A applied with a positive voltage (+V₁), a silicon oxide film is formed and electrons and negatively charged particles attracted to the positively charged target are deposited on it.

Subsequently, as shown in FIG. 4(d), when negative voltage (−V₂) is applied to target 63A, as shown in FIG. 4 (d), positively charged argon ions are strongly attracted to and collide with negative target 63A, by which the silicon oxide film formed on the surface of target 63A is removed.

Also, by applying a positive voltage (+V₁) to target 63B, a major part of electrons and negatively charged particles near target 63A applied with a negative voltage, migrate to the surface of target 63B applied with a positive voltage, and migration of these particles to substrate 30 is reduced. Thus, an extraordinary increase in temperature of substrate 30 is avoided and formation of high quality films becomes possible.

Thus, by structuring targets 63 and substrate 30 so as to satisfy Formula (1), the two targets become relatively closer to each other, and when, under this condition, +V₁ voltage is applied to one of the targets and −V₂ voltage is applied to the other target, a voltage difference between the two targets increases up to |V₁+V₂| volt which is considerably larger than the voltage differences between targets 63 and substrate 30, namely, |V₁| volt and |V₂| volt. Accordingly, a major part of charged particles such as argon ions, oxygen ions and electrons migrate between the two targets and migration of these particles to the substrate 30 is largely reduced. Thus, damage to the substrate (specifically the glass substrate) is avoided even when the applied voltage is increased, resulting in a higher production rate of high quality optical thin films without exhibiting cracking, peeling and white turbidity. Furthermore, the same effect is obtained not only for a glass substrate but also for a plastic substrate by assembling the sputtering apparatus so as to satisfy Formula (2).

By structuring the sputtering apparatus so as to satisfy Formula (3), since discharge occurring in the vicinity of targets 63 mainly locates in the portion between the two targets, reverse sputtering of the substrate surface 30 is reduced even when applied voltages are increased, and high rate formation of films becomes possible.

By structuring the sputtering apparatus so as to satisfy Formula (4), the electrical field is focused in the vicinity of substrate 30, and a high deposition rate of target materials is maintained, resulting in a high production rate of high quality optical films.

By rotating targets 63 while sputtering, any localized deformation of the targets while sputtering is avoided and an effective utilization of the targets is possible.

By structuring discharge gas inlet 71 on a back wall of target protection container 40 and structuring reactive gas inlet 70 between the targets and the substrate in vacuum chamber 2, a high distribution density of discharge gas in the vicinity of the targets, and a high distribution density of reactive gas in the vicinity of the substrate is attained, which results in the following effects: (i) in a process of forming a film by sputtering, a stable glow discharge in the vicinity of the targets is obtained, while formation of an oxide film on the target surface is avoided, which results in avoiding lowering of the film forming rate and in avoiding unstable discharge; and (ii) even if the target material is in a low oxidation state, oxidation of the target material in the vicinity of the target or on the substrate surface is promoted and a highly transparent optical film is obtained.

The above embodiment describes a sputtering apparatus having two targets 63 and two magnets 80 in vacuum chamber 2, however, the present invention is not limited thereto, and a sputtering apparatus having plural pairs of targets and magnets in vacuum chamber 2 is also included.

### The 2nd Embodiment of the Present Invention

The 2nd embodiment of the present invention will now be explained, however, the same assembles as in the 1st embodiment will not be explained again and will just be represented by the same designations (numbers).

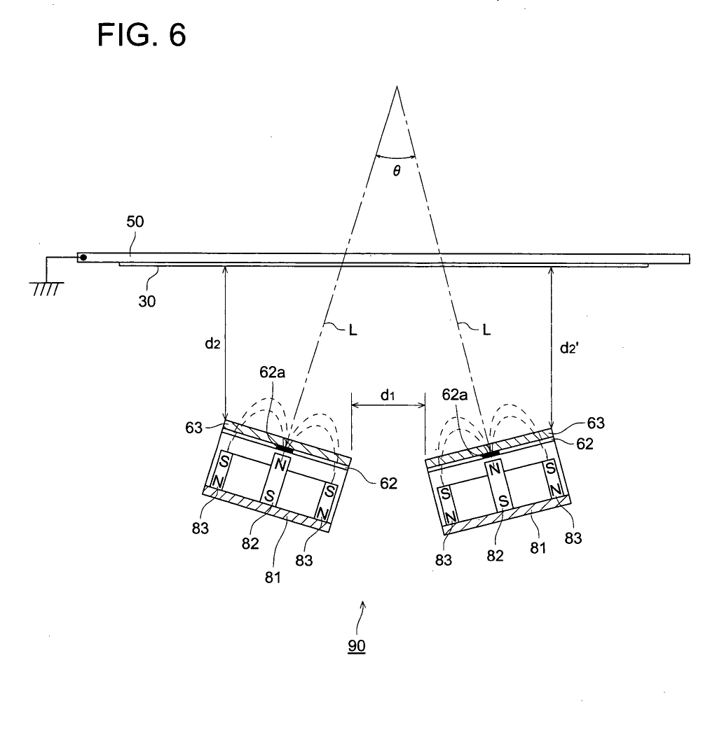

In the 2nd embodiment of the present invention, sputtering apparatus 90 is characterized by having two planar targets 63 and two planar target holders 62, as shown in FIG. 6.

An “N” pole of 1st magnet array 82 is assembled to face target holder 62. The sputtering apparatus is structured so as to satisfy Formula (3), namely θ≦160°, wherein, θ is defined as an angle between two perpendicular lines of the targets in a cross-section plane containing the two targets which is perpendicular to a side line of one of the planar targets.

The sputtering apparatus is also structured so as to satisfy Formula (1), namely, d1≦3d2, wherein, d1 is the distance between the closest points of the outer surfaces of the two targets 63, and d2 is any of distances between the outer surfaces of targets 63 and substrate 30, each distance being the shortest between target 63 and substrate 30.

The same effects described for the 1st embodiment are also obtained for sputtering apparatus 90 of the 2nd embodiment of the present invention.

### The 3rd Embodiment of the Present Invention

The 3rd embodiment of the present invention will now be explained, however, the same assembles as in the 1st embodiment will not again be explained and will just be represented by the same designations (numbers).

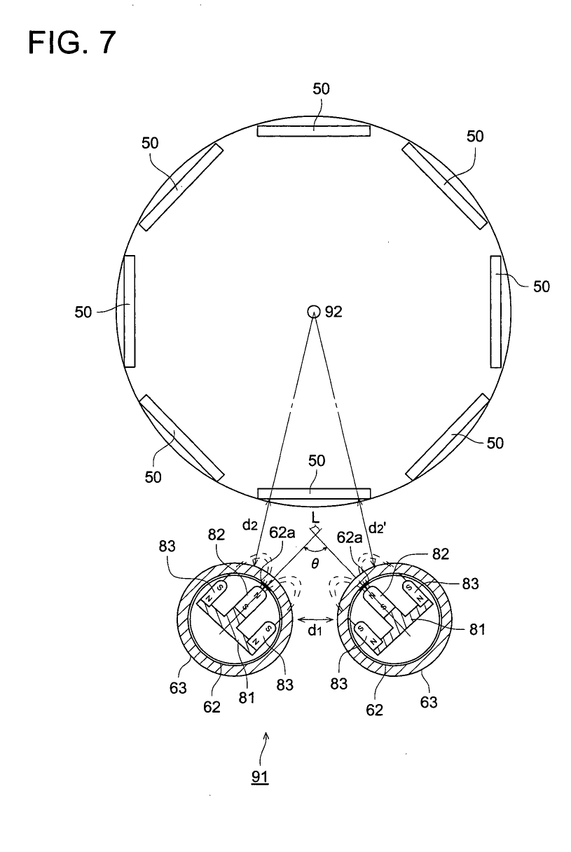

As shown in FIG. 7, the sputtering apparatus of the 3rd embodiment 91 contains a plurality of planar substrate holders which are provided on the circumference of the same circle and the substrates can be rotated on rotation axis 92 when sputtering is carried out.

The “N” pole of 1st magnet array 82 is placed to face the back surface of target holder 62a, and, similarly as in the 1st embodiment, the sputtering apparatus is structured so as to satisfy Formula (3), namely θ≦160°, wherein, θ is defined as the angle between two perpendicular lines of the target holders 62 in a cross-section plane containing two targets 63 which is perpendicular to a side line of one of the planar targets 63.

The sputtering apparatus is also structured so as to satisfy Formula (1), namely, d1≦3d2, wherein, d1 is the same as described in the 2nd embodiment of the present invention, and d2 is any of distances between the outer surfaces of targets 63 and substrate 30 when the substrate is moved to the point closest to two targets 63.

The same effects described for the 1st embodiment of the present invention are also obtained for the sputtering apparatus 91 of the 3rd embodiment of the present invention. Since sputtering apparatus 91 contains a plurality of substrate holders 50, effecient formation of thin films F using these substrate holders is carried out.

### EXAMPLES

The present invention will now be explained using inventive samples 1 to 14, however, the present invention is not limited thereto.

In each inventive sample, using the sputtering apparatus explained in the 1st embodiment (refer to FIG. 2), first, the vacuum chamber was evacuated down to a pressure of 3×10⁻³ Pa, followed by introducing argon as a discharge gas and oxygen as a reactive gas into the vacuum chamber. After the inside pressure of the vacuum chamber was stabilized, formation of a thin film was carried out on a glass or plastic substrate by applying a sinusoidal voltage wave for inventive samples 1 to 5 and 9 to 14, or a square voltage wave for inventive samples 6 to 8 to the target. Silicon was used as a target material inventive samples 1 to 9 and for comparative samples 1 and 2, and a low oxidation state titanium oxide was used for inventive samples 10 to 14 and for comparative sample 3.

Film forming conditions for inventive samples and comparative samples are shown in Table 1.

TABLE 1

| | | | | | | Concentration | Concentration | Applied | |
|---|---|---|---|---|---|---|---|---|---|
| | | | | | Sputtering | of | of | Voltag V1 | |
| | Target | d1 | d2/d2′ | Angle | Vacuum | Argon Gas | Oxygen Gas | (V) | Frequency |
| | Material | (mm) | (mm) | θ (°) | Level (Pa) | (SCCM) | (SCCM) | (V1 = V2, V3 = 0) | (kHz) |
| Inv. 1 | Silicon | 70 | 70/75 | 100 | 6 × 10⁻² | 10 | 12 | 500 | 70 |
| Inv. 2 | Silicon | 100 | 70/75 | 100 | 6 × 10⁻² | 10 | 12 | 500 | 70 |
| Inv. 3 | Silicon | 200 | 70/75 | 100 | 6 × 10⁻² | 10 | 12 | 500 | 70 |
| Comp. 1 | Silicon | 250 | 70/75 | 100 | 6 × 10⁻² | 10 | 12 | 500 | 70 |
| Inv. 4 | Silicon | 100 | 70/75 | 10 | 6 × 10⁻² | 10 | 12 | 500 | 70 |
| Inv. 5 | Silicon | 100 | 70/75 | 30 | 6 × 10⁻² | 10 | 12 | 500 | 70 |
| Inv. 6 | Silicon | 100 | 70/75 | 45 | 6 × 10⁻² | 10 | 12 | 500 | 70 |
| Inv. 7 | Silicon | 100 | 70/75 | 120 | 6 × 10⁻² | 10 | 12 | 500 | 70 |
| Inv. 8 | Silicon | 100 | 70/75 | 160 | 6 × 10⁻² | 10 | 12 | 500 | 70 |
| Comp. 2 | Silicon | 100 | 70/75 | 180 | 6 × 10⁻² | 10 | 12 | 500 | 70 |
| Inv. 9 | Silicon | 130 | 70/75 | 90 | 9 × 10⁻² | 20 | 24 | 1000 | 80 |
| Inv. 10 | *1 | 80 | 70/70 | 50 | 7 × 10⁻¹ | 200 | 24 | 1000 | 80 |
| Inv. 11 | *1 | 130 | 70/70 | 50 | 1 × 10⁻¹ | 200 | 24 | 1000 | 80 |
| Inv. 12 | *1 | 160 | 70/70 | 50 | 1 × 10⁻¹ | 200 | 24 | 1000 | 80 |
| Inv. 13 | *1 | 200 | 70/70 | 50 | 1 × 10⁻¹ | 200 | 24 | 1000 | 80 |
| Comp. 3 | *1 | 250 | 70/70 | 50 | 1 × 10⁻¹ | 200 | 24 | 1000 | 80 |
| Inv. 14 | *1 | 120 | 70/70 | 45 | 1 × 10⁻¹ | 200 | 24 | 800 | 70 |

*1: Low Oxidation State Titanium Oxide (TiOx x ≦ 2)
Inv.: Inventive Sample,
Comp.: Comparative Sample

Summarized in Table 2 are as follows: (i) film forming rate and evaluations; (ii) film qualities and evaluations; and (iii) overall evaluations, for the inventive samples of the present invention and comparative samples.

Evaluation criteria are as follows:

(Cracking)

A: Almost no cracking is observed;
B: Slight cracking is observed, however, the film is acceptable for practical usage; and
C: Considerable cracking is observed, and the film is not acceptable for practical usage.
   (White Turbidity)
A: Almost no white turbidity is observed;
B: Slight white turbidity is observed, however, the film is acceptable for practical usage; and
C: Considerable white turbidity is observed, and the film is not acceptable for practical usage.
   (Peeling)
A: Almost no peeling is observed;
B: Slight peeling is observed, however, the film is acceptable for practical usage; and
C: Considerable peeling is observed, and the film is not acceptable for practical usage.
   (Overall Evaluation)
A: Excellent;
B: Acceptable; and

C: Unacceptable.

TABLE 2

| | Glass Substrate (BK7) | | | | | | Plastic Substrate | | | | | | |
|---|---|---|---|---|---|---|---|---|---|---|---|---|---|
| | Film | | | | | | Film | | | | | | |
| | Forming | | Film Quarity | | | | Forming | | Film Quarity | | | | |
| | Rate | | Crack- | White | Peel- | | Rate | | Crack- | White | | | Overall |
| | (Å/sec) | Evaluation | ing | Turbidity | ing | Evaluation | (Å/sec) | Evaluation | ing | Turbidity | Peeling | Evaluation | Evaluation |
| Inv. 1 | 14 | A | A | A | A | A | 14 | A | A | A | A | A | A |
| Inv. 2 | 12 | A | A | A | A | A | 12 | A | A | A | A | A | A |
| Inv. 3 | 8 | B | A | A | A | A | 8 | B | A | C | A | A | B |
| Comp. 1 | 6 | B | A | C | A | C | 6 | B | A | C | A | C | C |
| Inv. 4 | 10 | A | A | A | A | A | 10 | A | A | C | A | C | C |
| Inv. 5 | 11 | A | A | A | A | A | 11 | A | A | C | A | C | C |
| Inv. 6 | 11 | A | A | A | A | A | 11 | A | A | A | A | A | A |
| Inv. 7 | 8 | B | A | A | A | A | 8 | B | A | A | A | A | A |
| Inv. 8 | 7 | B | A | A | A | A | 7 | B | A | A | A | A | B |
| Comp. 2 | 3 | C | A | A | A | A | 3 | C | A | A | A | A | C |
| Inv. 9 | 14 | A | A | A | A | A | 14 | A | A | A | A | A | A |
| Inv. 10 | 20 | A | A | A | A | A | 20 | A | A | A | A | A | A |
| Inv. 11 | 17 | A | A | A | A | A | 17 | A | A | A | A | A | A |
| Inv. 12 | 15 | A | A | A | A | A | 15 | A | A | C | A | C | B |
| Inv. 13 | 12 | A | A | A | A | A | 12 | A | A | C | A | C | B |
| Comp. 3 | 8 | B | A | C | A | C | 8 | B | C | C | A | C | C |
| Inv. 14 | 16 | A | A | A | A | A | 16 | A | A | A | A | A | A |

Inv.: Inventive Sample,
Comp.: Comparative Sample

Table 2 reveals that, low film forming rates and insufficient film qualities due to white turbidity on both glass and plastic substrates were observed for comparative sample 1 which were prepared under conditions of d1>3d2 (or 3d2′).

Alternatively, under a condition of d1≧2d2 (or 2d2′) and d1≦3d2 (or 3d2′), namely, Formula (1) was satisfied and Formula (2) was not satisfied, which is a case of inventive sample 3, a high quality film without white turbidity was obtained, but only on the glass substrate. Further, under conditions of d1≦2d2(or d2′), namely Formula (2) was also satisfied, which are the cases of inventive samples 1 and 2, a high quality film was obtained in high film forming rates on both glass and plastic substrates.

Under a condition of θ>160°, namely Formula (3) was not satisfied (a case of comparative sample 2), a high quality film was obtained, however, the film forming rate was not enough. Alternatively, under conditions of θ≦160°, namely, Formula (3) was satisfied and Formula (4) was not satisfied (cases of inventive samples 4, 5, 7 and 8), high quality films were obtained at least on glass substrates. Further, under conditions of 45≦θ≦100°, namely, Formula (4) was satisfied (cases of inventive samples 2, 6 and 9), high quality films were obtained on both glass and plastic substrates in high film forming rates.

In the case of comparative sample 3, namely, under the condition of d1>3d2 (or 3d2′) in which Formula (1) was not satisfied, film forming rate was not high enough and white turbidity was observed on the films formed on both glass and plastic substrates, indicating that the qualities of the films were not commercially viable.

In the cases of inventive samples 12 and 13, namely, under the condition of d1>2d2 (or 2d2′) and d1≦3d2 (or 3d2′) in which Formula (1) was satisfied and Formula (2) was not satisfied, high quality films free from white turbidity were formed, but only on glass substrates. Further, in the cases of inventive samples 10, 11 and 14, namely, under the conditions of d1≦2d2 (or 2d2′) in which Formula (2) was satisfied, high quality films were formed on both glass and plastic substrates in high film forming rates.

1. A sputtering apparatus for applying a thin film coating to a substrate comprising:
a vacuum chamber;
at least two cylindrical targets or two planar targets in the vacuum chamber; and
at least two magnets each juxtaposed respectively to each of the targets so as to generate a magnetic field in a vicinity of an outer surface of the target,
wherein:
(i) the thin film coating is formed by applying a voltage to each of the targets while a discharge gas and a reactive gas are introduced into the vacuum chamber,
(ii) Formula (1) is satisfied in the vacuum chamber,
d1≦3d2 Formula (1)
provided that d1 is a distance between the outer surfaces of the two targets and d2 is any one of distances between the outer surfaces of the targets and the substrate.

2. The sputtering apparatus of claim 1, wherein, Formula (2) is satisfied in the vacuum chamber.
d1≦2d2 Formula (2)

3. The sputtering apparatus of claim 1, wherein, Formula (3) is satisfied in the vacuum chamber.
θ≦160 Formula (3)
provided that:
(i) when the two targets are cylindrical, θ is defined as an angle between two normal lines drawn on outer circles of the targets in a cross-section plane containing the two targets, which is perpendicular to a side surface of one of the cylindrical targets, each normal line being drawn at a point where the magnetic field is strongest in the outer circle; and
(ii) when the two targets are planar, θ is defined as an angle between two perpendicular lines of the targets in a cross-section plane containing the two targets, which is perpendicular to a side line of one of the planar targets.

4. The sputtering apparatus of claim 3, wherein, Formula (4) is satisfied in the vacuum chamber.
45°≦θ≦100° Formula (4)

5. The sputtering apparatus of claim 1, wherein, the targets are cylindrical and the targets rotate in circumferential directions while sputtering.

6. The sputtering apparatus of claim 1 further comprising a protection container which surrounds the targets and has an aperture open to a front,
wherein, the protection container has a discharge gas inlet on a back wall, while a reactive gas inlet is provided at a portion of the vacuum chamber between the targets and the substrate.

7. The sputtering apparatus of claim 1, wherein, polarities of electrical power supplied to the two targets are different from each other and change with time.
